(19) United States
(12) Patent Application Publication
(10) Pub. No.: US 2016/0276181 A1
(43) Pub. Date: Sep. 22, 2016

(54) SUBSTRATE CLEANING APPARATUS AND SUBSTRATE CLEANING METHOD

(71) Applicant: KABUSHIKI KAISHA TOSHIBA, Tokyo (JP)

(72) Inventor: Masato KURITA, Yokkaichi (JP)

(21) Appl. No.: 14/847,839

(22) Filed: Sep. 8, 2015

(30) Foreign Application Priority Data
Mar. 17, 2015 (JP) 2015-053248

(51) Int. Cl. H01L 21/67; B08B 1/00

(52) U.S. Cl. CPC H01L 21/67046; B08B 1/006

(57) ABSTRACT

In one embodiment, a substrate cleaning apparatus includes a plurality of rollers configured to hold and rotate a substrate. The apparatus further includes one or more cleaning members provided to one or more rollers of the plurality of rollers. Furthermore, the plurality of rollers are configured to hold the substrate so that the one or more cleaning members come into contact with a side face of the substrate.

### CROSS REFERENCE TO RELATED APPLICATION

This application is based upon and claims the benefit of priority from the prior Japanese Patent Application No. 2015-53248, filed on Mar. 17, 2015, the entire contents of which are incorporated herein by reference.

### FIELD

Embodiments described herein relate to a semiconductor cleaning apparatus and a semiconductor cleaning method.

### BACKGROUND

After a semiconductor wafer is polished, various deposits stick to front and back faces of the wafer. Examples of the deposits include residues of a polishing agent (slurry residues) and polishing waste. Therefore, if the wafer after the polishing is not sufficiently cleaned, a leakage current occurs at a portion where the deposits are remaining, and the deposits cause adhesion failure. This results in a decrease in reliability of a semiconductor device.

Scrub cleaning is known as a method for cleaning the front and back faces of the semiconductor wafer after the polishing. In the scrub cleaning, the front and back faces of the wafer is cleaned by bringing a roll sponge into contact with the front and back faces of the wafer and rotating the wafer and the roll sponge. However, there is a problem that the scrub cleaning cannot remove the deposits on a rounded side face (bevel portion) of the wafer. The deposits on the bevel portion contaminate a substrate cleaning apparatus and other semiconductor manufacturing facilities.

### BRIEF DESCRIPTION OF THE DRAWINGS

FIG. 1 is a cross-sectional view illustrating a structure of a substrate cleaning apparatus of a first embodiment;

FIG. 2 is a top view illustrating the structure of the substrate cleaning apparatus of the first embodiment;

FIGS. 3A and 3B are cross-sectional views illustrating a structure of a roller of the first embodiment;

FIG. 4 is a graph indicating a cleaning result of a semiconductor wafer in the first embodiment; and

FIG. 5 is a flow chart illustrating a substrate cleaning method of the first embodiment.

### DETAILED DESCRIPTION

Embodiments will now be explained with reference to the accompanying drawings.

In one embodiment, a substrate cleaning apparatus includes a plurality of rollers configured to hold and rotate a substrate. The apparatus further includes one or more cleaning members provided to one or more rollers of the plurality of rollers. Furthermore, the plurality of rollers are configured to hold the substrate so that the one or more cleaning members come into contact with a side face of the substrate.

### First Embodiment

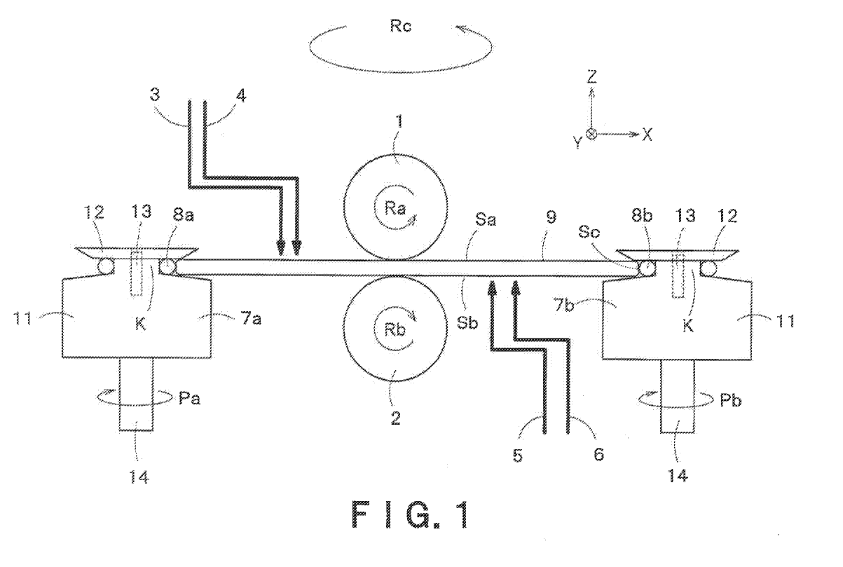

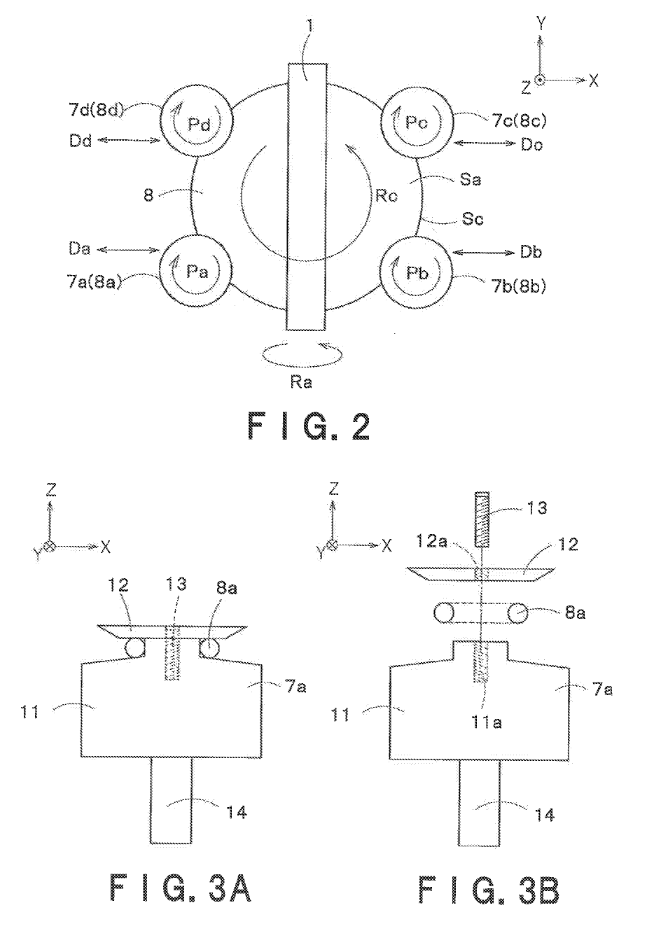

FIGS. 1 and 2 are a cross-sectional view and a top view illustrating a structure of a substrate cleaning apparatus of a first embodiment, respectively.

The substrate cleaning apparatus of the present embodiment includes first and second roll sponges 1 and 2, a first chemical supply nozzle 3, a first pure water supply nozzle 4, a second chemical supply nozzle 5, a second pure water supply nozzle 6, a plurality of rollers 7a to 7d, and a plurality of bevel cleaning sponges 8a to 8d. The bevel cleaning sponges 8a to 8d are examples of one or more cleaning members. The substrate cleaning apparatus of the present embodiment is used to clean a semiconductor wafer 9 by scrub cleaning. The semiconductor wafer 9 is an example of a substrate.

Each of the rollers 7a to 7d includes a lower member 11 as an example of a first member, an upper member 12 as an example of a second member, a screw 13, and a roller driver 14. Although FIG. 1 only illustrates a structure of the rollers 7a and 7b, the rollers 7c and 7d also have the same structure.

Details of the substrate cleaning apparatus of the present embodiment will be now described with reference to FIG. 1 mainly. FIG. 2 is also appropriately referred to in the description.

The semiconductor wafer 9 has a front face Sa, a back face Sb, and a rounded side face (bevel portion) Sc. FIG. 1 indicates X and Y directions parallel to the front face Sa of the semiconductor wafer 9 and perpendicular to each other, and indicates a Z direction perpendicular to the front face Sa of the semiconductor wafer 9. In the description described herein, +Z direction is assumed to be an upper direction, and −Z direction is assumed to be a lower direction. For example, a positional relation between the first and second roll sponges 1 and 2 is expressed as that the second roll sponge 2 is arranged lower than the first roll sponge 1. The −Z direction of the present embodiment may or may not correspond to a gravity direction.

The first and second roll sponges 1 and 2 are cleaning members for cleaning the front face Sa and the back face Sb of the semiconductor wafer 9, respectively. The first and second roll sponges 1 and 2 of the present embodiment are formed of polyvinyl alcohol (PVA). In the scrub cleaning of the present embodiment, the front face Sa and the back face Sb are cleaned by bringing the first and second roll sponges 1 and 2 into contact with the front face Sa and the back face Sb and rotating the semiconductor wafer 9 and the first and second roll sponges 1 and 2. Arrows Ra, Rb and Rc indicate rotation directions of the first roll sponge 1, the second roll sponge 2 and the semiconductor wafer 9, respectively.

Each of the first and second roll sponges 1 and 2 of the present embodiment has a cylindrical shape extending in the Y direction and rotates around an axis parallel to the Y direction. Also, the semiconductor wafer 9 of the present embodiment rotates around an axis parallel to the Z direction.

The first chemical supply nozzle 3 and the first pure water supply nozzle 4 supply a chemical liquid and pure water to the front face Sa of the semiconductor wafer 9, respectively. The second chemical supply nozzle 5 and the second pure water supply nozzle 6 supply a chemical liquid and pure water to the back face Sb of the semiconductor wafer 9, respectively. These liquids are supplied in the scrub cleaning of the present embodiment.

The rollers 7a to 7d are used to hold and rotate the semiconductor wafer 9. The rollers 7a to 7d can be opened and closed as indicated by arrows Da to Dd illustrated in FIG. 2. When the semiconductor wafer 9 is attached to and removed from the rollers 7a to 7d, the rollers 7a to 7d open and close. The rollers 7a to 7d of the present embodiment open and close in ±X directions. Also, the rollers 7a to 7d can rotate as indicated by arrows Pa to Pd illustrated in FIG. 2. When the rollers 7a to 7d rotate as indicated by the arrows Pa to Pd, the semiconductor wafer 9 rotates as indicated by the arrow Rc. The rollers 7a to 7d of the present embodiment rotate around an axis parallel to the Z direction.

The rollers 7a to 7d of the present embodiment are arranged around the semiconductor wafer 9 at intervals of 90° as illustrated in FIG. 2. The rollers 7a and 7d are arranged on the −X direction side of the first and second roll sponges 1 and 2. The rollers 7b and 7c are arranged on the +X direction side of the first and second roll sponges 1 and 2.

The bevel cleaning sponges 8a to 8d have ring shapes and are respectively attached to the rollers 7a to 7d. The bevel cleaning sponges 8a to 8d of the present embodiment are formed of PVA as similar to the first and second roll sponges 1 and 2. The thickness in the Z direction of the semiconductor wafer 9 of the present embodiment is 0.775 mm. The thickness (diameter) in the Z direction of the bevel cleaning sponges 8a to 8d of the present embodiment is 10 mm.

The rollers 7a to 7d of the present embodiment hold the semiconductor wafers 9 so that the bevel cleaning sponges 8a to 8d come into contact with the side face Sc of the semiconductor wafer 9. When the rollers 7a to 7d rotate as indicated by the arrows Pa to Pd, the bevel cleaning sponges 8a to 8d rotate as indicated by the arrows Pa to Pd as well. Rotation of the rollers 7a to 7d is transmitted to the semiconductor wafer 9 via the bevel cleaning sponges 8a to 8d, and thereby the semiconductor wafer 9 is rotated as indicated by the arrow Rc. In this case, the side face Sc of the semiconductor wafer 9 is cleaned with the bevel cleaning sponges 8a to 8d. The chemical liquids and the pure water to be supplied to the front face Sa and the back face Sb of the semiconductor wafer 9 also reach to the side face Sc of the semiconductor wafer 9 and are used to clean the side face Sc.

In the present embodiment, bevel cleaning sponge(s) may be attached to only a part of the rollers 7a to 7d, and ring shape member(s) which do not have a cleaning function may be attached to remaining rollers 7a to 7d. An example of the ring shape members includes rubber members. Also, the number of the rollers 7a to 7d in the substrate cleaning apparatus of the present embodiment may be any number other than four.

FIGS. 3A and 3B are cross-sectional views illustrating a structure of the roller 7a of the first embodiment. The following description is also applied to the rollers 7b to 7d.

The bevel cleaning sponge 8a is attached between an upper face of the lower member 11 and a lower face of the upper member 12 as illustrated in FIG. 3A. The upper member 12 is detachably fixed to the lower member 11. The bevel cleaning sponge 8a can be attached to and removed from the roller 7a by removing the upper member 12 from the lower member 11. Therefore, when the bevel cleaning sponge 8a is worn out or becomes dirty, the bevel cleaning sponge 8a can be exchanged in the present embodiment.

The lower member 11 includes a protrusion K. The bevel cleaning sponge 8a is embedded around the protrusion K. The upper member 12 is fastened to the protrusion K of the lower member 11 by the screw 13. The upper member 12 can be attached to and removed from the lower member 11 by attaching and removing the screw 13 (FIG. 3B). A reference sign 11a indicates a screw hole of the lower member 11. A reference sign 12a indicates a screw hole of the upper member 12. The upper member 12 may be fastened to the lower member 11 by two or more screws 13. Also, the upper member 12 may be fastened to the lower member 11 by a fastening member other than the screw 13.

An interval between the above upper face of the lower member 11 and the above lower face of the upper member 12 is preferably set so that the bevel cleaning sponge 8a comes into contact with both of the upper and lower faces thereof. This is because inclination in the Z direction at the position of the bevel cleaning sponge 8a can be prevented. Therefore, the above interval is preferably set to approximately 10 mm in the present embodiment.

The roller driver 14 is a module for rotating and opening/closing the roller 7a. The roller driver 14 can open and close the roller 7a as indicated by the arrow Da (FIG. 2). The roller driver 14 can rotate the roller 7a as indicated by the arrow Ra (FIG. 2).

As described above, the substrate cleaning apparatus of the present embodiment includes the bevel cleaning sponges 8a to 8d provided to the rollers 7a to 7d. Therefore, according to the present embodiment, the side face Sc of the semiconductor wafer 9 can be cleaned at a portion where the semiconductor wafer 9 is held. Specifically, a module for holding the semiconductor wafer 9 in the present embodiment (the rollers 7a to 7d and the bevel cleaning sponges 8a to 8d) can clean the side face Sc of the semiconductor wafer 9 in addition to holding the semiconductor wafer 9.

In the present embodiment, the first and second roll sponges 1 and 2 can clean the front face Sa and the back face Sb of the semiconductor wafer 9, and simultaneously the bevel cleaning sponges 8a to 8d can clean the side face Sc of the semiconductor wafer 9. According to the present embodiment, deposits such as residues of a polishing agent and polishing waste can be removed from the semiconductor wafer 9 by cleaning the front face Sa, the back face Sb, and the side face Sc of the semiconductor wafer 9 after the polishing.

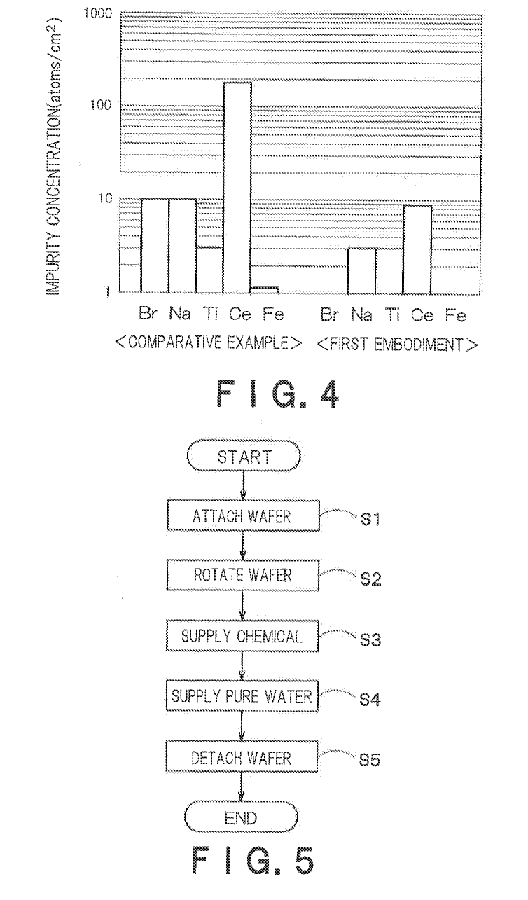

FIG. 4 is a graph indicating a cleaning result of the semiconductor wafer 9 in the first embodiment.

FIG. 4 illustrates measurement results of impurity concentrations of the side face Sc of the semiconductor wafer 9 in a case where the semiconductor wafer 9 is cleaned by using the substrate cleaning apparatus of the first embodiment. FIG. 4 further illustrates measurement results of impurity concentrations of the side face Sc of the semiconductor wafer 9 in a case where the semiconductor wafer 9 is cleaned by using a substrate cleaning apparatus of a comparative example. The substrate cleaning apparatus of the comparative example has a configuration in which the bevel cleaning sponges 8a to 8d of the first embodiment are switched to ring shape members without a cleaning function.

FIG. 4 illustrates surface concentrations of bromine (Br), sodium (Na), titanium (Ti), cerium (Ce) and iron (Fe) on the side face Sc of the semiconductor wafer 9. Ce is generally used for the polishing agent of the semiconductor wafer 9.

FIG. 4 indicates that a Ce concentration of the side face Sc of the semiconductor wafer 9 of the first embodiment is lower than a Ce concentration of the side face Sc of the semiconductor wafer 9 of the comparative example. More specifically, the Ce concentration of the first embodiment is less than 1/10 of the Ce concentration of the comparative example. In this manner, according to the first embodiment, the residues of the polishing agent are effectively cleaned and removed from the side face Sc of the semiconductor wafer 9.

FIG. 5 is a flow chart illustrating a substrate cleaning method of the first embodiment. The substrate cleaning method illustrated in FIG. 5 is performed by using the substrate cleaning apparatus of FIGS. 1 and 2.

First, the rollers 7a to 7d are opened, the semiconductor wafers 9 are inserted among the rollers 7a to 7d, and then the rollers 7a to 7d are closed. In this manner, the semiconductor wafers 9 are attached to the rollers 7a to 7d (step S1).

Next, the rollers 7a to 7d start rotating. Thereby, the semiconductor wafers 9 held by the rollers 7a to 7d start rotating (step S2).

Chemical liquids are then supplied from the first and second chemical supply nozzles 3 and 5 to the front face Sa and the back face Sb of the semiconductor wafer 9 (step S3). In this case, since the semiconductor wafer 9 is rotating, these chemical liquids also reach to the side face Sc of the semiconductor wafer 9 by the action of a centrifugal force. In step S3, the first and second roll sponges 1 and 2 are rotated by bringing them into contact with the front face Sa and the back face Sb, respectively. In this manner, the front face Sa, the back face Sb and the side face Sc of the semiconductor wafer 9 are cleaned.

When the semiconductor wafer 9 has been cleaned by the chemical liquids, pure water is supplied to the front face Sa and the back face Sb of the semiconductor wafer 9 from the first and second pure water supply nozzles 4 and 6 (step S4). In this case, since the semiconductor wafer 9 is rotating, the pure water also reaches to the side face Sc of the semiconductor wafer 9 by the action of a centrifugal force. In this manner, the chemical liquids are washed off from the front face Sa, the back face Sb and the side face Sc of the semiconductor wafer 9.

Next, the rollers 7a to 7d are opened, the semiconductor wafers 9 are removed from the rollers 7a to 7d, and then the rollers 7a to 7d are closed. In this manner, the semiconductor wafers 9 are detached from the rollers 7a to 7d (step S5).

As described above, the substrate cleaning apparatus of the present embodiment includes the bevel cleaning sponges 8a to 8d provided to the rollers 7a to 7d. These rollers 7a to 7d hold the semiconductor wafers 9 so that the bevel cleaning sponges 8a to 8d come into contact with the side face Sc of the semiconductor wafer 9. Therefore, according to the present embodiment, the side face Sc of the semiconductor wafer 9 can be cleaned with the cleaning sponges 8a to 8d, and the deposits on the side face Sc of the semiconductor wafer 9 can be cleaned and removed.

While certain embodiments have been described, these embodiments have been presented by way of example only, and are not intended to limit the scope of the inventions. Indeed, the novel apparatuses and methods described herein may be embodied in a variety of other forms; furthermore, various omissions, substitutions and changes in the form of the apparatuses and methods described herein may be made without departing from the spirit of the inventions. The accompanying claims and their equivalents are intended to cover such forms or modifications as would fall within the scope and spirit of the inventions.

1. A substrate cleaning apparatus comprising:
a plurality of rollers configured to hold and rotate a substrate; and
one or more cleaning members provided to one or more rollers of the plurality of rollers,
wherein the plurality of rollers are configured to hold the substrate so that the one or more cleaning members come into contact with a side face of the substrate.

2. The apparatus of claim 1, wherein the cleaning members have ring shapes.

3. The apparatus of claim 1, wherein the cleaning members are sponges.

4. The apparatus of claim 1, wherein the cleaning members are formed of polyvinyl alcohol.

5. The apparatus of claim 1, wherein the one or more rollers are configured so that the cleaning members can be attached to and removed from the rollers.

6. The apparatus of claim 1, wherein each of the one or more rollers comprises a first member, and a second member fixed to the first member,
each of the cleaning members being provided between the first member and the second member.

7. The apparatus of claim 6, wherein each of the cleaning members has a ring shape and is embedded around a protrusion of the first member.

8. The apparatus of claim 7, wherein the second r member is fixed to the protrusion of the first member.

9. The apparatus of claim 6, wherein the first member and the second member are fastened by a fastening member.

10. The apparatus of claim 1, further comprising:
a first roll cleaning member configured to clean a first face of the substrate; and
a second roll cleaning member configured to clean a second face of the substrate.

11. The apparatus of claim 10, further comprising:
a first liquid supply module configured to supply a liquid to the first face of the substrate; and
a second liquid supply module configured to supply a liquid to the second face of the substrate.

12. A substrate cleaning method comprising:
preparing a plurality of rollers including one or more rollers to which one or more cleaning members are provided;
holding a substrate by the plurality of rollers so that the one or more cleaning members come into contact with a side face of the substrate; and
cleaning the side face of the substrate with the one or more cleaning members by rotating the substrate by the plurality of rollers.

13. The method of claim 12, wherein the cleaning members have ring shapes.

14. The method of claim 12, wherein the cleaning members are sponges.

15. The method of claim 12, wherein the cleaning members are formed of polyvinyl alcohol.

16. The method of claim 12, wherein the one or more rollers are configured so that the cleaning members can be attached to and removed from the rollers.

17. The method of claim 12, wherein each of the one or more rollers comprises a first member, and a second member fixed to the first member,
each of the cleaning members being provided between the first member and the second member.

18. The method of claim 17, wherein each of the cleaning members has a ring shape and is embedded around a protrusion of the first member.

19. The method of claim 18, wherein the second member is fixed to the protrusion of the first member.

20. The method of claim 17, wherein the first member and the second member are fastened by a fastening member.
